(19) United States
(12) Patent Application Publication
(10) Pub. No.: US 2010/0140100 A1
(43) Pub. Date: Jun. 10, 2010

(54) MANUFACTURING METHOD OF PRINTED CIRCUIT BOARD

(75) Inventors: Woon-Chun KIM, Suwon-si (KR); Soon-Gyu Yim, Seongnam-si (KR); Young-Ju Kim, Suwon-si (KR); Hwa-Jan Jung, Ansan-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/482,122

(22) Filed: Jun. 10, 2009

(30) Foreign Application Priority Data
Dec. 8, 2008 (KR) 10-2008-0123922

(51) Int. Cl. H05K 3/10; C25D 5/02

(52) U.S. Cl. 205/125

(57) ABSTRACT

Disclosed is a method of manufacturing a printed circuit board. The method can include providing a carrier formed with a release layer, performing a roughening treatment on the release layer such that the release layer has surface roughness, forming a circuit pattern on the release layer, stacking the carrier on an insulating layer such that the circuit pattern is buried in the insulating layer, and separating the release layer and the carrier from the insulating layer and the circuit pattern.

### CROSS-REFERENCE TO RELATED APPLICATIONS

This application claims the benefit of Korean Patent Application No. 10-2008-0123922, filed with the Korean Intellectual Property Office on Dec. 8, 2008, the disclosure of which is incorporated herein by reference in its entirety.

### BACKGROUND

1. Technical Field

The present invention relates to a method of manufacturing a printed circuit.

2. Description of the Related Art

With electronic devices becoming smaller, thinner and faster, there has been a growing demand for thin-film and high speed printed circuit boards. Accordingly, there have been studies on printed circuit boards in which circuit patterns are buried in an insulator.

In the conventional art, a circuit pattern is formed by using a carrier on which a copper foil is stacked, and the carrier is stacked on an insulating layer and is pressed to bury the circuit pattern in the insulating layer. The printed circuit board, in which the circuit pattern is buried in the insulating layer, is then fabricated by sequentially removing the carrier and the copper foil.

In such conventional art, however, it has been difficult to remove the carrier and impossible to reuse the carrier because the carrier is removed by etching. Moreover, since the thin copper foils are relatively thicker, with the thickness of 3 micrometers or greater, the circuit pattern is easily damaged when the copper foils are removed by etching, thereby limiting the implementation of a fine circuit pattern.

### SUMMARY

The present invention provides a method of manufacturing a printed circuit board that can form a finer circuit pattern and bury the formed circuit pattern in an insulator and easily remove a carrier.

An aspect of present invention features a method of manufacturing a printed circuit board. The method of manufacturing a printed circuit board in accordance with an embodiment of the present invention can include: providing a carrier formed with a release layer; performing a roughening treatment on the release layer such that the release layer has surface roughness; forming a circuit pattern on the release layer; stacking a carrier on an insulating layer such that the circuit pattern is buried in the insulating layer; and separating the release layer and the carrier from the insulating layer and the circuit pattern.

Here, the circuit pattern can be formed by plating.

There can be a further process of forming a seed layer on the release layer, between the performing of the roughening treatment on the release layer and the forming of the circuit pattern.

The separating of the release layer and the carrier can also include separating the release layer and the carrier from the seed layer.

### BRIEF DESCRIPTION OF THE DRAWINGS

FIG. 1 is a flowchart showing a method of manufacturing a printed circuit board in accordance with an embodiment of the present invention;

FIG. 2 through FIG. 10 are cross-sectional views showing each process of a method of manufacturing a printed circuit board in accordance with an embodiment of the present invention;

FIG. 11 through FIG. 18 are cross-sectional views showing each process of a method of manufacturing a printed circuit board in accordance with another embodiment of the present invention; and

FIG. 19 through FIG. 25 are cross-sectional views showing each process of a method of manufacturing a printed circuit board in accordance with yet another embodiment of the present invention.

### DETAILED DESCRIPTION

A method of manufacturing a printed circuit board in accordance with certain embodiments of the present invention will be described in detail with reference to the accompanying drawings. Throughout the drawings, similar or identical elements are given the same reference numerals. Throughout the description of the present invention, when describing a certain technology is determined to evade the point of the present invention, the pertinent detailed description will be omitted.

When one element is described “to form”, “being formed on” or “forming” another element, it shall be construed as being formed on another element directly but also as possibly having yet another element in between.

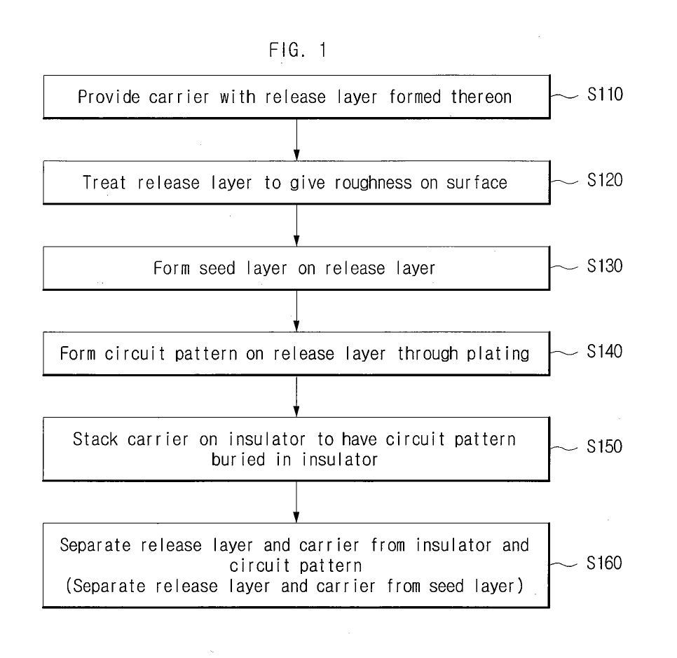

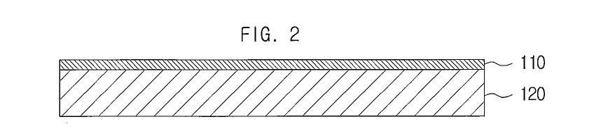

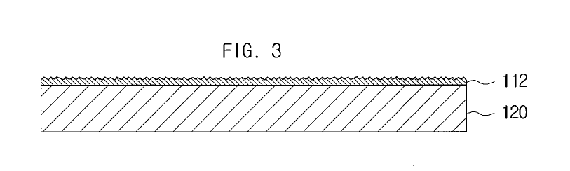

FIG. 1 is a flowchart showing a method of manufacturing a printed circuit board in accordance with an embodiment of the present invention, and FIG. 2 through FIG. 10 are cross-sectional views showing each process of a method of manufacturing a printed circuit board in accordance with an embodiment of the present invention.

As shown in FIG. 1, the method of manufacturing a printed circuit board in accordance with this embodiment of the present invention can include providing a carrier 120 in which a release layer 110 is formed, performing a roughening treatment of the release layer 110 such that the release layer 110 has surface roughness, forming a circuit pattern 140 on the release layer 112, stacking the carrier 120 on an insulator 150 such that the circuit pattern is buried in the insulator 150, and separating the release layer 112 and the carrier 120 from the insulator 150 and the circuit pattern 140.

In accordance with the present embodiment, it is possible to form a finer circuit pattern 140 and bury the formed circuit pattern 140 in the insulating layer 150 and simultaneously remove the carrier 120 without any difficulty, by performing the roughening treatment of the release layer 110 in order to allow the release layer 110 to have surface roughness.

Hereinafter, each process will be described with reference to FIG. 1 through FIG. 10.

In the process represented by S110, the carrier 120, on which a release layer 110 is formed, can be provided, as shown in FIG. 2. Here, the carrier 120 can be made of metal, glass, polymer, silicon, or ceramic and used to bury the circuit pattern 140 in the insulating layer. At this time, the release layer 110 can be formed on a surface of the carrier 120 such that the carrier 120 is easily separated from the circuit pattern 140 after the circuit pattern 140 is buried in the insulating layer 150.

The release layer 110 is made of resin that can be made rough on the surface through a roughening treatment. This material may not be completely removed but can form roughness on the surface due to its tolerance despite the exposure to, for example, a desmear process.

Such release layer 110 can be made of an epoxy-series composition disclosed in Korean patent publication number 2007-0070255 or various other materials that can have surfaces formed with roughness by the roughening treatment.

On the other hand, the release layer 110 can be formed on the carrier 120 by a method such as coating. The release layer 110 coated on the carrier 120 can have surface roughness by being cured by heat or ultraviolet rays and then undergoing a roughening treatment process.

Then, in the process represented by S120, the roughening treatment can be performed on the release layer 110 such that the release layer 110 has a surface roughness. In particular, the release layer 110 can be formed and cured on the carrier 120, and then a surface of the release layer 110 can undergo the roughening treatment to form the surface roughness on the release layer 110. Accordingly, it is possible to increase an adhesive force between the release layer and the circuit pattern 140 or the seed layer 130, which will be formed on the release layer 112.

Here, the roughening treatment process can be performed by etching a surface of the release layer 112 by use of an etchant (e.g. alkali solution), which is reactive with the release layer 112. The roughening treatment process can be simultaneously performed when a desmear process for removing the smear of an inner wall of a via hole is performed.

As such, the surface area of the release layer 112 can be increased by forming the surface roughness on the release layer, which is used for easy separation of the carrier 120 from the circuit pattern 140. Accordingly, the seed layer 130 or the circuit pattern 140 can be formed by depositing conductive particles on the release layer 112 by, for example, plating, thereby increasing an adhesive strength between the seed layer 130 or the circuit pattern 140 and the release layer 112. This can form the circuit pattern 140 more finely.

In more detail, the seed layer 130 can be formed on the release layer 112, and the circuit pattern 140 can be formed on the seed layer 130 by a semi-additive process, which will be described later, in accordance with an embodiment of the present invention. Accordingly, if the surface area of the release layer 112 is increased by performing the roughening treatment of the release layer 112, the thin seed layer 130 can be formed. Thus, when the seed layer 130 is removed by the flash etching later, this has little effect on the circuit pattern 140, thereby more finely forming the circuit pattern 140.

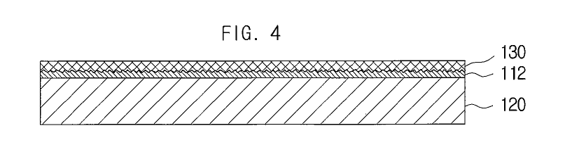

Next, in the process represented by S130, the seed layer 130 can be formed on the release layer 112, as shown in FIG. 4. As described below, since the circuit pattern 140 is formed by the semi-additive process in accordance with this embodiment of the present invention, the seed layer 130 can be firstly formed on the release layer 112 by an electroless plating to form the circuit pattern 140.

The aforementioned roughening treatment process can increase the surface area of the release layer 112, thereby increasing an adhesive strength between the seed layer 130 and the release layer 112. Accordingly, it is possible to form the surface of the release layer 112 more thinly by the electroless plating.

As such, the seed layer 130 can be thinly formed by the roughening treatment of the release layer 112. Accordingly, when the seed layer 130 is removed by flash-etching after the circuit pattern 140 is formed, this may cause little damage of the circuit pattern 140. As a result, the circuit pattern 140 can be formed more finely.

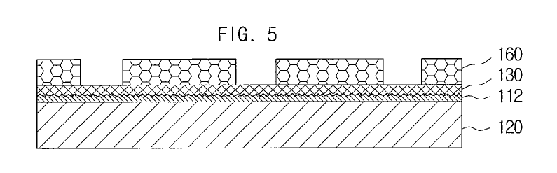

Next, in the process represented by S140, the circuit pattern 140 can be formed on the release layer 112 by plating, as shown in FIG. 5 through FIG. 7. This process can be broken down as described below.

Firstly, the plating resist layer 160 can be formed on the seed layer 130, excluding areas where the circuit pattern 140 is to be formed, as shown FIG. 5. This process can be performed by forming the plating resist layer 160 on the overall surface of the seed layer 130 and then removing a part of the seed layer 130 by photo-lithography.

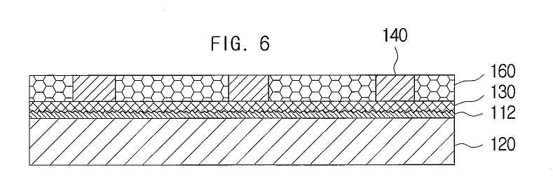

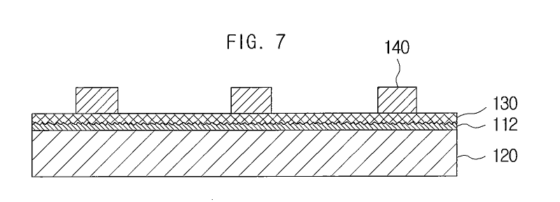

Then, the circuit pattern 140 can be formed on the seed layer by plating, as shown in FIG. 6, and then the remaining plating resist layer 160 can be removed, as shown in FIG. 7.

Next, in the process represented by S150, the carrier 120 can be stacked on the insulating layer 150 such that the circuit pattern 140 is buried in the insulating layer 150. In particular, it is possible to bury the circuit pattern 140 in the insulating layer 150 by stacking and pressing the carrier 120 having the release layer 112 formed with the seed layer 130 and the circuit pattern 140 on a surface of the insulating layer 150.

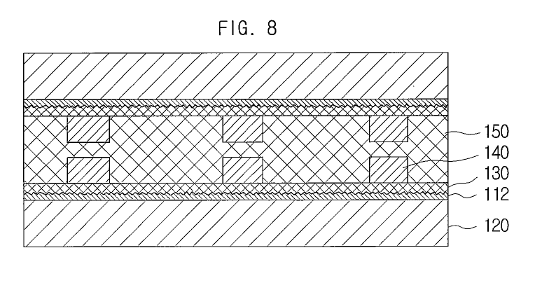

In this process, a pair of carriers 120 can be stacked and pressed on either side of the insulating layer 150, as shown in FIG. 8, and accordingly, a printed circuit pattern 100, in which the circuit pattern 140 is buried, can be implemented.

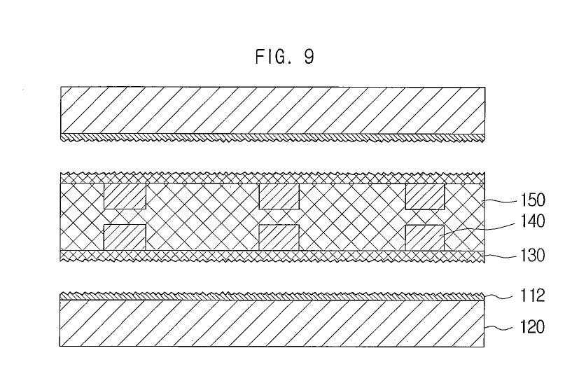

Next, in the process represented by S160, the release layer 112 and the carrier 120 can be separated from the insulating layer 150 and the circuit pattern 140, as shown in FIG. 9. In accordance with this embodiment of the present invention, the seed layer 130 can be formed on the release layer 112 by the semi-additive process, and then the circuit pattern 140 can be formed on the seed layer 130. This can allow the release layer 112 to directly be in contact with the seed layer 130. Accordingly, it is possible to separate the release layer and the carrier from the insulating layer 150 and the circuit pattern 140 by separating the release layer 112 and the carrier 120 from the seed layer 130.

At this time, by performing the roughening treatment such that the release layer 112 has the surface roughness, it is possible to acquire an adhesive strength between the release layer 112 and the seed layer 130 when the seed layer 130 is formed. The release layer 112 and the seed layer 130, however, can be made of resin and a metal, respectively. Accordingly, the adhesive strength between the release layer 112 and the seed layer 130 may be restricted, thereby allowing the release layer 112 and the seed layer 130 to be easily separated from each other.

In this case, by using the release layer 112, it is possible to easily separate the carrier 120 without etching. Accordingly, the carrier 120 can be re-used in the process of manufacturing other printed circuit boards or other parts.

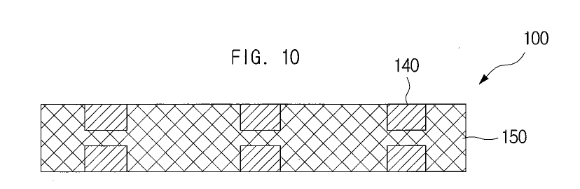

Then, the seed layer 130 can be removed as shown in FIG. 10. It is possible to manufacture a printed circuit board 100, in which the circuit pattern 140 is buried in the insulating layer 150, by removing the seed layer 130 exposed to the surface after the release layer 112 is separated from the carrier 120.

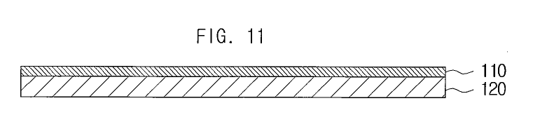

Hereinafter, a method of manufacturing a printed circuit board 100 in accordance with another embodiment of the present invention will be described with FIG. 11 through FIG. 18.

FIG. 11 through FIG. 18 are cross-sectional views showing each process of the method of manufacturing the printed circuit board 100 in accordance with another embodiment of the present invention.

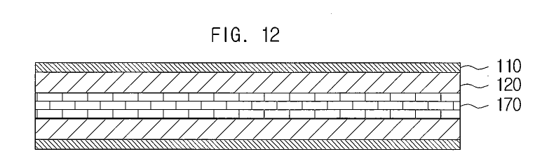

In accordance with this embodiment of the present invention, in the process represented by S110, the carrier 120 formed with the release layer 110 can be provided, as shown in FIG. 11, and then a pair of carrier 120, formed with the release layer 110, can be stacked by interposing a foam resin 170, as shown in FIG. 12.

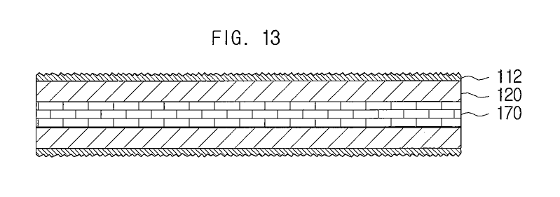

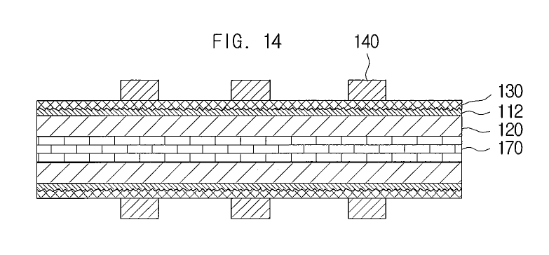

Then, in the process represented by S120, the roughening treatment of the release layer 110 can be performed such that the release layer 112 can have surface roughness, as shown in FIG. 13, and in the process represented by S130, the seed layer 130 can be formed on the release layer 112, as shown in FIG. 14. In the process represented by S140, the circuit pattern 140 can be formed on the release layer by plating.

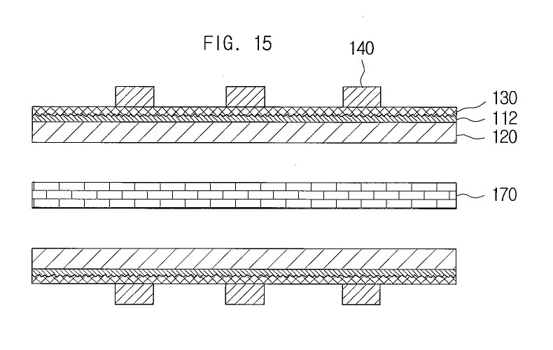

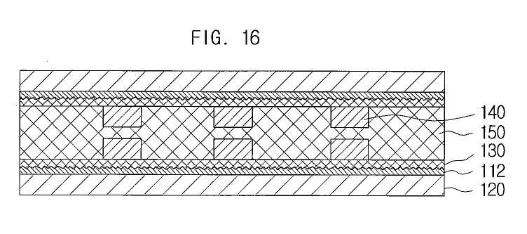

Thereafter, in the process represented by S150, the foam resin 170 can be foamed to separate the pair of carriers 120 from each other, as shown in FIG. 15, and the carrier 120 can be stacked on the insulating layer 150 such that the circuit pattern 140 is buried in the insulating layer 150, as shown in FIG. 16.

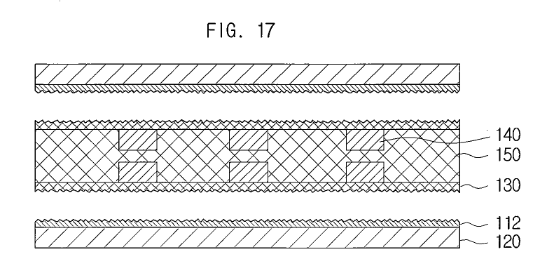

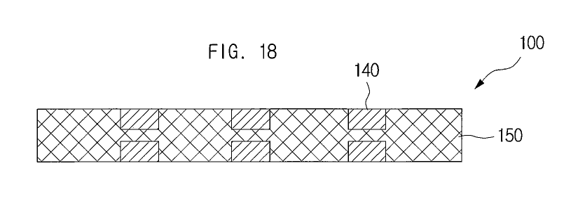

Next, in the process represented by S160, the release layer 112 and the carrier 120 can be separated from the insulating layer 150 and the circuit pattern 140, as shown in FIG. 17, and the seed layer 130 can be removed, as shown in FIG. 18.

This embodiment of the present invention has the same or similar sequence of processes and details as those of the aforementioned embodiment, except for additional processes of interposing the foam resin 170 and stacking the pair of carrier 120 formed with the release layer 110 on the foam resin 170, as shown in FIG. 12, and of foaming the foam resin 170 to separate the pair of carriers 120 from each other, as shown in FIG. 15. Accordingly, this embodiment of the present invention will be described on the basis of difference between the two embodiments of the present invention with reference to FIG. 12 through FIG. 15.

In accordance with this embodiment of the present invention, it is possible to save the process time and process cost by simultaneously performing the roughness treatment of the pair of release layers 110 formed on the pair of carriers, respectively, through a single process. For this, a process shown in FIG. 12 can be performed.

In particular, the foam resin 170 can be interposed between the pair of carriers 120 formed with the release layer 110, and the pair of carriers 120 can be pressed and stacked on the foam resin 170. Accordingly, it is possible to form the surface roughness on the release layer 112 as shown FIG. 13 and to simultaneously form the seed layer 130 and the circuit pattern 140 on each of the pair of release layers 112 by a single process, as shown in FIG. 14, by performing the roughening treatment of each of the pair of release layers 112.

In accordance with this embodiment of the present invention, it is possible to simultaneously perform the roughening treatment of a pair of release layers 112 and simultaneously form the seed layer 130 and the circuit pattern 140 on the pair of release layers 112 through a single process, thereby saving the process time and process cost.

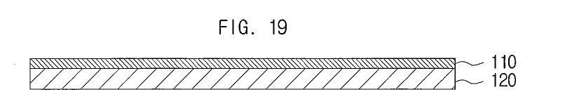

Hereinafter, a method of manufacturing a printed circuit board 100 in accordance with yet another embodiment of the present invention will be described with FIG. 19 through FIG. 25.

FIG. 19 through FIG. 25 are cross-sectional views showing each process of a method of manufacturing a printed circuit board in accordance with yet another embodiment of the present invention.

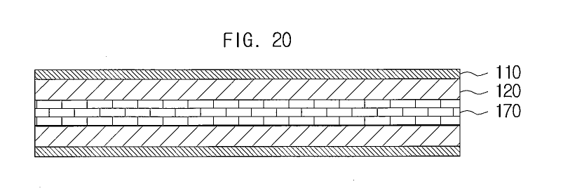

In this embodiment of the present invention, in the process represented by S110, the carrier 120 formed with the release layer 110 can be provided as shown in FIG. 19, and then the pair of carriers 120, on which the release layer is formed, can be stacked by interposing the foam resin 170, as shown in FIG. 20.

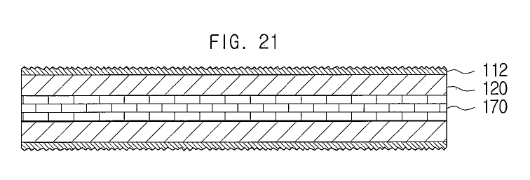

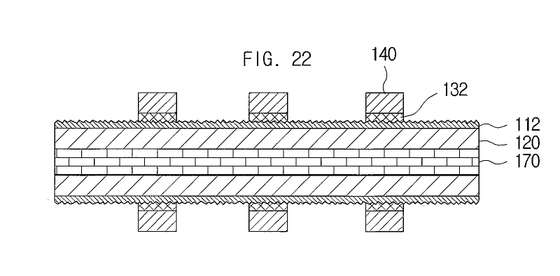

Thereafter, in the process represented by S120, the roughening treatment of the release layer 110 can be performed such that the release layer 112 has surface roughness, as shown in FIG. 21. Then, in the process represented by S130, the seed layer 130 can be formed on the release layer 112, as shown in FIG. 22, and in the process represented by S140, the circuit pattern 140 can be formed on the release layer 112 by plating. Thereafter, the seed layer exposed by the flash-etching can be removed.

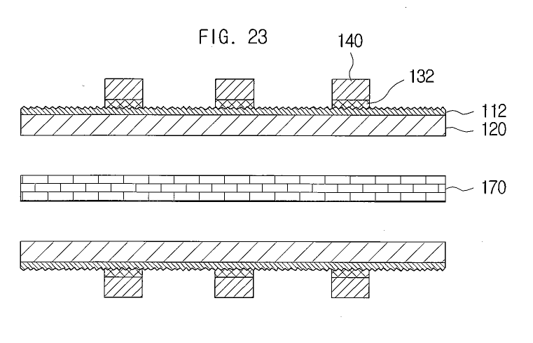

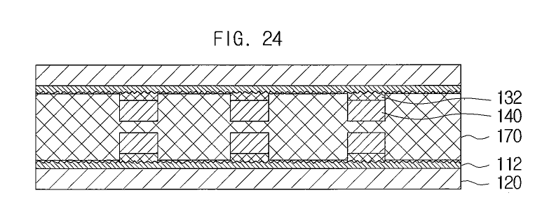

Then, in the process represented by S150, the foam resin 170 can be foamed to separate the pair of carriers 120 from each other, as shown in FIG. 23, and the carrier 120 can be stacked on the insulating layer 150 such that the circuit pattern 140 is buried in the insulating layer 150, as shown in FIG. 24.

Thereafter, in the process represented by S160, the release layer 12 and the carrier 120 can be separated from the insulating layer 150 and the circuit pattern 140.

This embodiment of the present invention has the same or similar sequence of processes and details as those of the aforementioned embodiment, except that the process of removing the seed layer 130 exposed by flash-etching is performed prior to the process represented by S150, which stacks the carrier 120 on the insulating layer 150. Accordingly, this embodiment of the present invention will be described on the basis of difference between the two embodiments of the present invention with reference to FIG. 22 through FIG. 25.

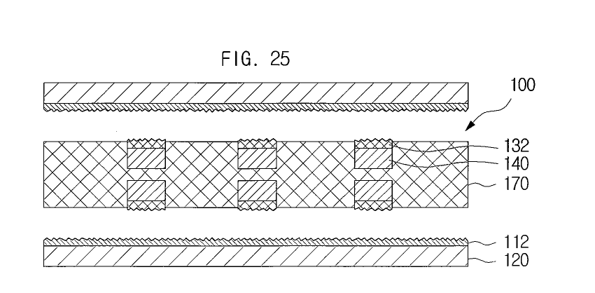

In this embodiment of the present invention, in the process represented by S130, the seed layer 130 can be formed on the release layer 112, as shown in FIG. 22, and in the process represented by S140, the circuit pattern 140 can be formed on the release layer 112 by plating. Thereafter, a seed 132 placed at a position corresponding to the position of the circuit pattern 140 can remain by removing the seed layer 130 exposed by flash etching. Accordingly, since the circuit pattern 140 and the seed 132 can be buried in the insulating layer 150, as shown in FIG. 25, this may not require the flash etching after the release layer 112 and the carrier 120 are separated from each other, as compared with the aforementioned embodiments of the present invention.

Hitherto, although some embodiments of the present invention have been shown and described, it will be appreciated by any person of ordinary skill in the art that a large number of modifications, permutations and additions are possible within the principles and spirit of the invention, the scope of which shall be defined by the appended claims and their equivalents.

What is claimed is:

1. A method of manufacturing a printed circuit board, the method comprising:
providing a carrier formed with a release layer;
performing a roughening treatment on the release layer such that the release layer has surface roughness;
forming a circuit pattern on the release layer;
stacking a carrier on an insulating layer such that the circuit pattern is buried in the insulating layer; and
separating the release layer and the carrier from the insulating layer and the circuit pattern.

2. The method of claim 1, wherein the forming of the circuit pattern is performed by plating.

3. The method of claim 2, further comprising forming a seed layer on the release layer, between the performing of the roughening treatment on the release layer and the forming of the circuit pattern.

4. The method of claim 3, wherein the separating of the release layer and the carrier comprises separating the release layer and the carrier from the seed layer.
